(19) United States
(12) Patent Application Publication
(10) Pub. No.: US 2025/0183140 A1
(43) Pub. Date: Jun. 5, 2025

(54) INTEGRATED CIRCUIT PACKAGES AND METHODS OF FORMING THE SAME

(71) Applicant: Taiwan Semiconductor Manufacturing Co., Ltd., Hsinchu (TW)

(72) Inventor: Tzu-Sheng Tseng, Hsinchu (TW)

(21) Appl. No.: 18/526,496

(22) Filed: Dec. 1, 2023

(51) Int. Cl. H01L 23/498; H01L 21/48; H01L 21/56; H01L 23/00

(52) U.S. Cl. CPC H01L 23/49822; H01L 21/4857; H01L 21/563; H01L 23/49894; H01L 24/16; H01L 24/32; H01L 24/73; H01L 24/92; H01L 2224/16227; H01L 2224/32225; H01L 2224/73204; H01L 2224/92125

(57) ABSTRACT

A semiconductor package and the method of forming the same are provided. The semiconductor package may include an integrated circuit package component having a semiconductor die and a package substrate physically and electrically connected to the integrated circuit package component on a first side of the package substrate. The package substrate may include a plurality of routing layers and an electrical circuit device embedded in the routing layers. Each routing layer may include an insulating layer having a polymer base and conductive features extending through the insulating layer. The electrical circuit device may be electrically connected to the integrated circuit package component by the conductive features of the plurality of routing layers.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A, 1B, 2A, 2B, 3A, 3B, 4, 5, 6, 7, 8, 9A, 9B, 9C, 10, 11, 12, and 13 are cross-sectional and top-down views of intermediate stages in the manufacturing process of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, an integrated circuit package comprises an integrated circuit package component and a package substrate. The package substrate may comprise one or more electrical circuit devices embedded in the package substrate. The package substrate may also comprise a plurality of routing layers with woven glass fabrics embedded in the routing layers. By embedding the one or more electrical circuit devices in the package substrate, the sizes of the package substrate and the integrated circuit package may be reduced, the functionalities of the package substrate and the integrated circuit package may be enhanced, and the electrical performance of the package substrate and the integrated circuit package may be improved. Further, by using the routing layers with the woven glass fabrics in the package substrate, the risk of inducing cracks in the package substrate during manufacturing of the package substrate may be prevented or reduced, thereby improving the reliability of the package substrate.

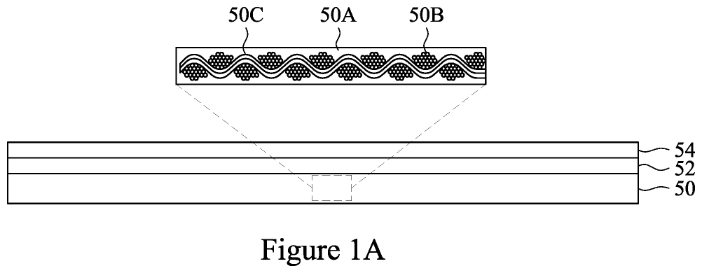

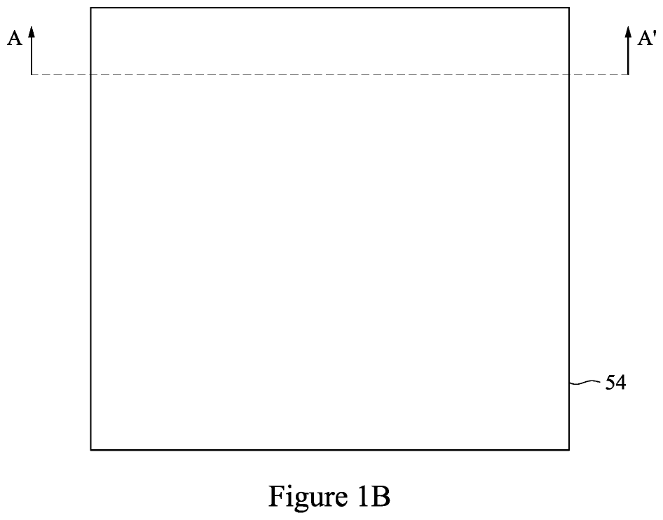

FIGS. 1A through 11 illustrate a manufacturing process of a package substrate comprising an embedded electrical circuit device. Embedding the electrical circuit device in the package substrate may reduce a size of the package substrate, enhance the functionality of the package substrate, and improve the electrical performance of the package substrate as discussed in greater detail below. FIGS. 1A, 2A, 3A, 4, 5, 6, 7, 8, 9A, 9C, 10, and 11 shown cross-sectional views, which may be obtained along reference cross-section AA′ in the top-down views shown in FIGS. 1B, 2B, 3B, and 9B, wherein like numerals refer to like features formed by like processes.

In FIGS. 1A and 1B, a carrier 50 with a first release layer 52 and a second release layer 54 are shown. Structural details of a portion of the carrier 50 are provided for illustrative purposes. The carrier 50 may comprise a polymer base 50A, fillers 50B embedded in the polymer base 50A, and a woven glass fabric 50C embedded in the polymer base 50A. The polymer base 50A may comprise resin or the like and the fillers 50B may comprise silicon dioxide or the like. The woven glass fabric 50C may comprise glass fibers woven together in a crisscross pattern, which may lead to a high degree of hardness of the carrier 50. The woven glass fabric 50C may be referred as a core of the carrier 50 and the polymer base 50A may be coated on the woven glass fabric 50C. The first release layer 52 may be a metal layer comprising copper or the like, which may be formed on the carrier 50 by plating or the like. The second release layer 54 may be metal layer comprising copper or the like, which may be laminated on the first release layer 52 by heat pressing or the like. The second release layer 54 may be easily detached from the first release layer 52 by peeling or the like. In some embodiments, the carrier 50, the first release layer 52, and the second release layer 54 may be a rectangular shape in the top-down view.

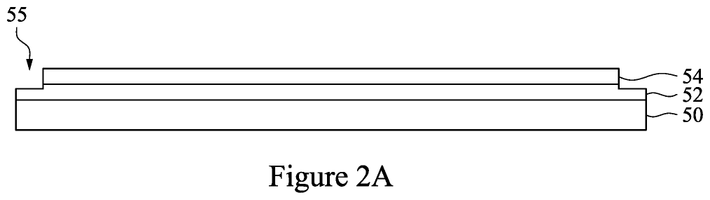

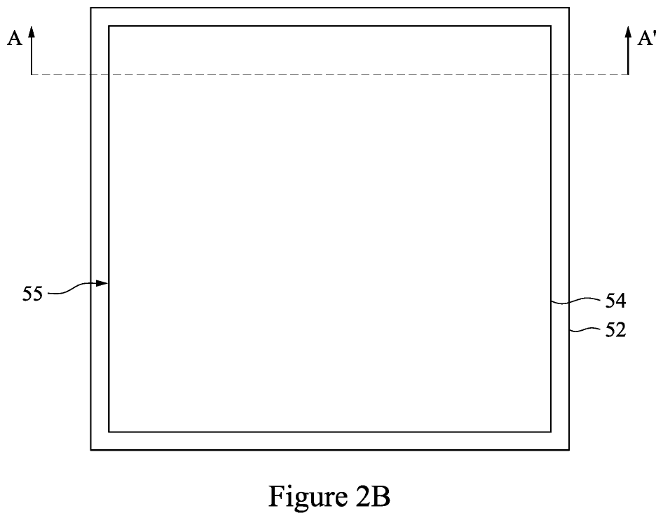

In FIGS. 2A and 2B, an opening 55 is formed by removing a portion of the first release layer 52 and a portion of the second release layer 54 along edges of the carrier 50. Sidewalls of the opening 55 may comprise sidewalls of the remaining second release layer 54 and sidewalls of an upper portion of the remaining first release layer 52 that may be level with the sidewalls of the remaining second release layer 54. The opening 55 may encircle the remaining second release layer 54 and the upper portion of the remaining first release layer 52 in the top-down view. The removal may be done by a suitable photolithography patterning process or the like.

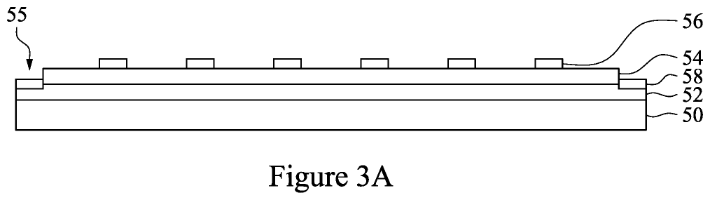

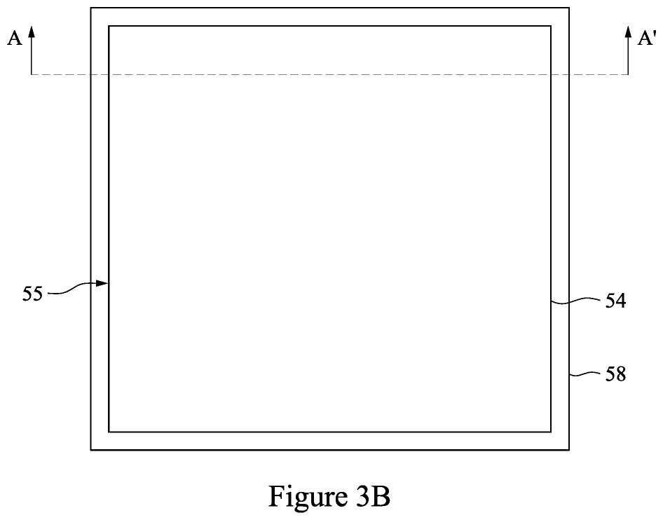

In FIGS. 3A and 3B, a sealing ring 58 is formed in the opening 55 and conductive features 56 are formed on the second release layer 54. The conductive features 56 are omitted in FIG. 3B for illustrative purposes. The sealing ring 58 may seal the first release layer 52 and the second release layer 54 together and may prevent delamination of the second release layer 54. As described in greater detail below, once the sealing ring 58 is removed, the second release layer 54 may be easily detached from the first release layer 52 by peeling or the like. The sealing ring 58 may extend on the sidewalls of the second release layer 54 and sidewalls of the upper portion of the first release layer 52. The sealing ring 58 may encircle the second release layer 54 and the upper portion of the first release layer 52 in the top-down view. The sealing ring 58 may be a metal layer comprising copper or the like, which may be formed in the opening 55 by plating or the like. The conductive features 56 may be formed of copper or the like. The conductive features 56 may be formed by plating or the like followed by a suitable photolithography patterning process or the like. Alternatively, a photoresist may be deposited and patterned to include openings that correspond to the conductive features 56, and the conductive features 56 may be formed in the openings with a plating process or the like. Subsequently, the photoresist may be removed. In some embodiments, the sealing ring 58 and the conductive features 56 are formed simultaneously by a same process, and the sealing ring 58 and the conductive features 56 have substantially same thickness. In some embodiments, the sealing ring 58 and the conductive features 56 are formed sequentially by different processes.

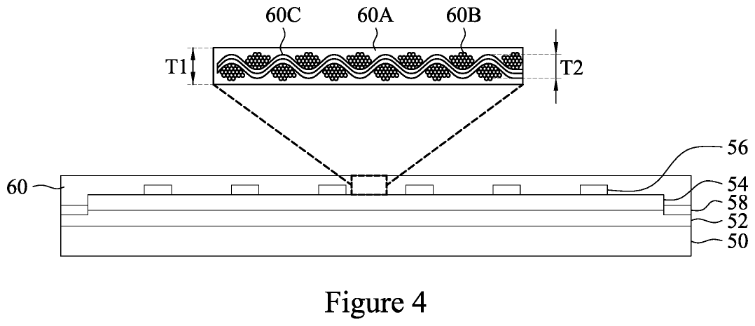

In FIG. 4, an insulating layer 60 is laminated on the conductive features 56 and the second release layer 54. Structural details of a portion of the insulating layer 60 are provided for illustrative purposes. The insulating layer 60 may have a same or similar composition to the carrier 50. The insulating layer 60 may comprise a polymer base 60A, fillers 60B embedded in the polymer base 60A, and a woven glass fabric 60C embedded in the polymer base 60A. The polymer base 60A may comprise resin or the like and the fillers 60B may comprise silicon dioxide or the like. The woven glass fabric 60C may comprise glass fibers woven together in a crisscross pattern, which may lead to a high degree of hardness of the insulating layer 60. The woven glass fabric 60C may be referred to as a core of the insulating layer 60 and the polymer base 60A may be coated on the woven glass fabric 60C. In some embodiments, the insulating layer 60 may be an Ajinomoto build-up film with Glass Cloth Primer (ABF-GCP).

The lamination process may comprise a placement step and a molding step. During the placement step, the insulating layer 60 may be placed on the conductive features 56. Then during the molding step, the insulating layer 60 may be heated to a temperature above the melting point of the polymer base 60A and pressed towards the second release layer 54. The melted polymer base 60A may move downwards and fills the gaps between the insulating layer 60 and the second release layer 54 as well as with the sealing ring 58. The woven glass fabric 60C may remain intact during the lamination process. After the lamination process, the insulating layer 60 may have a thickness T1 in a range between about 15 μm and about 40 μm. The woven glass fabric 60C may have a thickness T2. A ratio R1 of the thickness T2 to the thickness T1 may be in range between about 0.4 and about 0.9, which may lead to robust mechanical properties of the insulating layer 60.

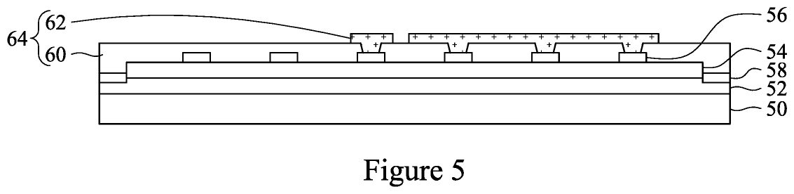

In FIG. 5, conductive features 62 are formed on and through the insulating layer 60. The conductive features 62 may comprise conductive lines extending on a surface of the insulating layer 60 and conductive vias extending through the insulating layer 60 to be physically and electrically connected to some or all of the conductive features 56. The conductive features 56 that are not physically and electrically connected to the conductive features 62 may be dummy features, as described in greater detail below. The conductive features 62 may be formed by first forming openings through the insulating layer 60, including the polymer base 60A and the woven glass fabric 60C, by laser drilling or the like, and forming a conductive material such as copper or the like in the openings and on the remaining surface of the insulating layer 60 by plating or the like. The openings may expose the conductive features 56 underneath the insulating layer 60 and the conductive material may be physically and electrically connected to the exposed conductive features 56. Then a suitable photolithography patterning process may be done to pattern the conductive material into the conductive features 62. Forming openings through the insulating layer 60 may be referred to as patterning the insulating layer 60. The conductive vias of the conductive features 62 may have a trapezoidal shape and may extend through the woven glass fabric 60C of the insulating layer 60. In some embodiments, the conductive vias of the conductive features 62 contact the woven glass fabric 60C of the insulating layer 60. The insulating layer 60 and the conductive features 62 may be collectively referred to as a routing layer 64.

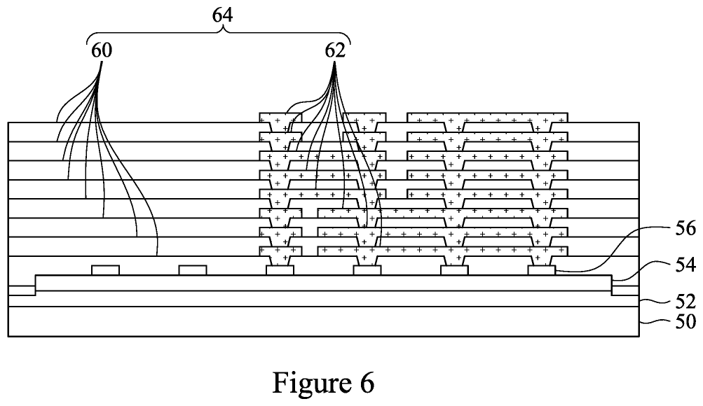

In FIG. 6, more routing layers 64 are formed over the carrier 50 by repeating the processes described with respect to FIGS. 4 and 5. Each of the conductive lines of the conductive features 62 may be between neighboring insulating layers 60 and each of the conductive vias of the conductive features 62 may extend through the corresponding insulating layer 60. The routing layers 64 formed over the carrier 50 may be referred to as a first plurality of the routing layers 64. A portion of the first plurality of the routing layers 64 may be free of the conductive features 62, where an electrical circuit device may be subsequently embedded as described in greater detail below. FIG. 6 shows interfaces between the polymer bases 60A of neighboring routing layers 64 for illustrative purposes. In some embodiments, interfaces exist between the polymer bases 60A of neighboring routing layers 64. In some embodiments, the polymer bases 60A of neighboring routing layers 64 merge together during the molding steps of the corresponding lamination process.

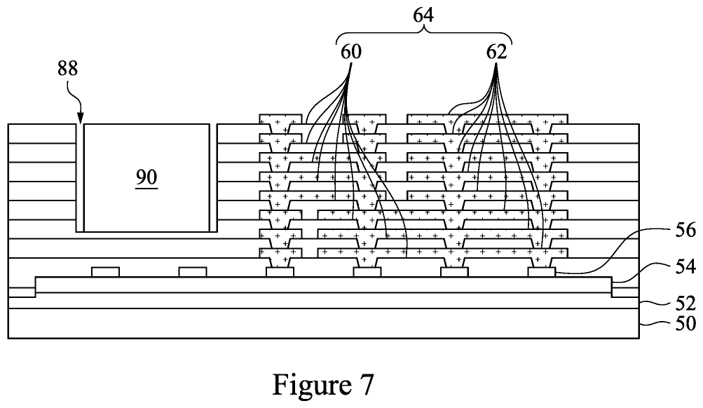

In FIG. 7, a cavity 88 is formed in the first plurality of the routing layers 64 and an electrical circuit device 90 is placed in the cavity 88. The cavity 88 may be formed in the portion of the first plurality of the routing layers 64 free of the conductive features 62. The cavity 88 may be formed by laser drilling or the like and may have a trapezoidal or rectangular shape with straight sidewalls. Forming the cavity 88 through the insulating layers 60 may be referred to as patterning the insulating layers 60. The cavity 88 may extend through one or more insulating layers 60. Due to the high degree of hardness of the insulating layers 60, the risk of inducing cracks in the first plurality of the routing layers 64 during the formation of the cavity 88 may be prevented or reduced, thereby improving the reliability of the subsequently formed package substrate. Then the electrical circuit device 90 may be placed in the cavity 88. The electrical circuit device 90 may be isolated from the conductive features 62 of the first plurality of the routing layers 64 and the conductive features 56. Portions of the conductive features 62 may be disposed beside the electrical circuit device 90. The electrical circuit device 90 may be an integrated passive device (IPD), such as resistor, capacitor (e.g., multilayer ceramic capacitor), voltage regulator (e.g., integrated voltage regulator, coupled inductor voltage regulator), inductor, or the like.

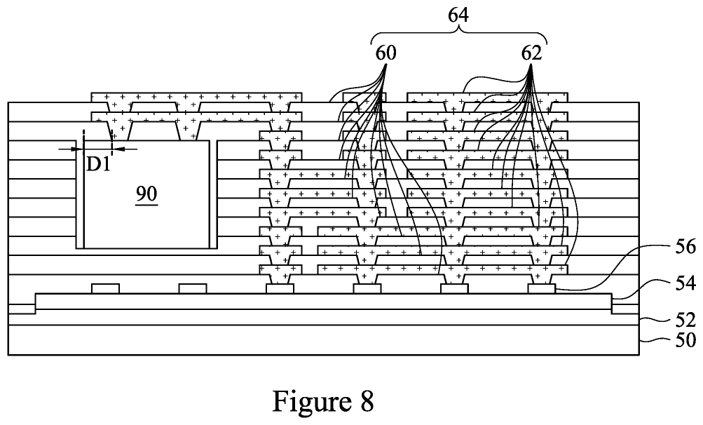

In FIG. 8, more routing layers 64 are formed over the first plurality of the routing layers 64 and the electrical circuit device 90 by repeating the processes described with respect to FIGS. 4 and 5. The routing layers 64 formed over the electrical circuit device 90 may be referred to as a second plurality of the routing layers 64. The polymer base 60A of the routing layer 64 in contact with a surface of the electrical circuit device 90 may fill the gaps between the electrical circuit device 90 and the first plurality of the routing layers 64 upon melting during the molding step of the corresponding lamination process, which may stabilize the electrical circuit device 90 in the cavity 88. The material of the polymer base 60A may extend on sidewalls of the electrical circuit device 90. In some embodiments, sidewalls of the electrical circuit device 90 are completely covered by the material of polymer base 60A. In some embodiments, sidewalls of the electrical circuit device 90 are partially covered by the material of the polymer base 60A. Some conductive vias of the conductive features 62 in the second plurality of the routing layers 64 may be physically and electrically connected to the electrical circuit device 90. Such conductive vias may be spaced apart from the sidewalls of the electrical circuit device 90 by a distance Di larger than 25 μm. When the distance Di is larger than 25 μm, the conductive vias may have good electrical contact with the electrical circuit device 90.

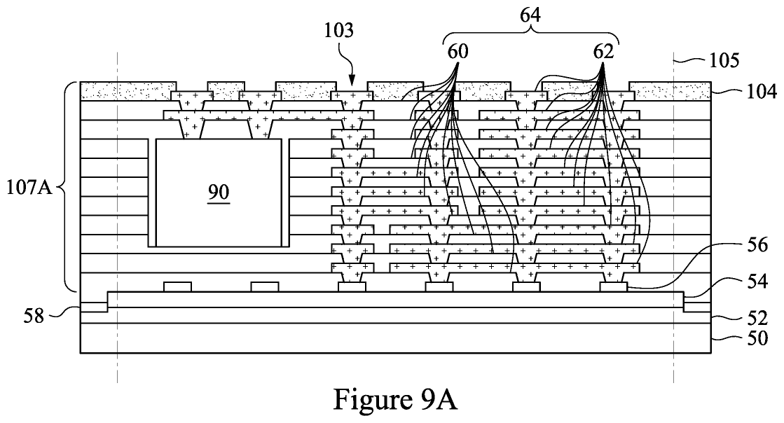

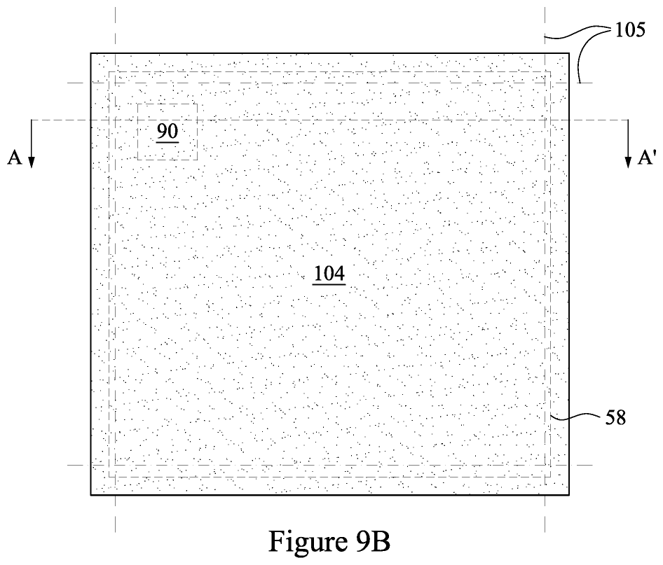

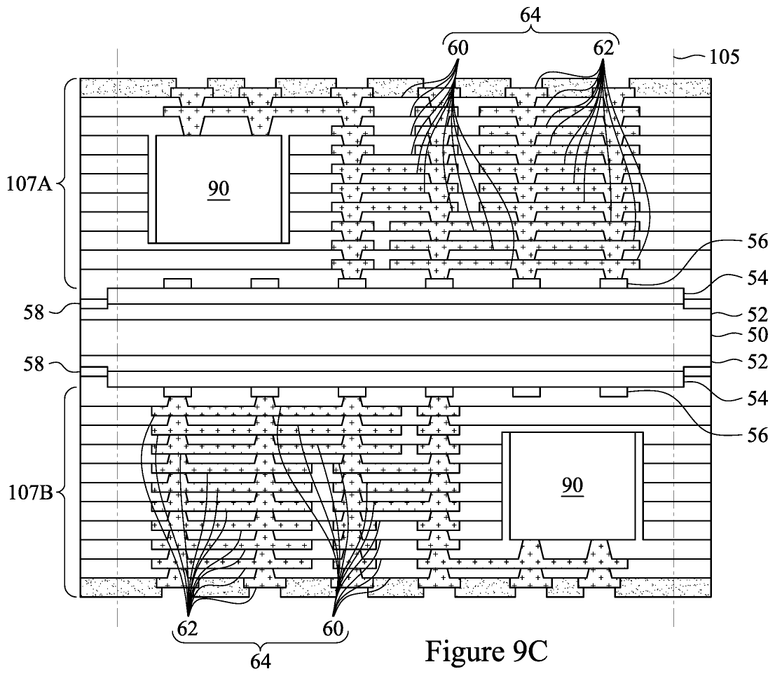

In FIGS. 9A and 9B, a protective layer 104 is formed on the second plurality of the routing layers 64 and the sealing ring 58 is removed along scribed lines 105. The conductive features 62 are omitted, and the sealing ring 58 as well as the electrical circuit device 90 are shown in dashed lines in FIG. 9B for illustrative purposes. The protective layer 104 may be first formed over the top the routing layer 64 of the second plurality of the routing layers 64 and then patterned to form openings 103 which expose the corresponding conductive features 62. The protective layer 104 may comprise solder resist (e.g., epoxy, polymer) or the like. The structure over the second release layer 54 shown in FIG. 9A may be referred to as the structure 107A. In the embodiments where the carrier 50 has a rectangular shape in the top-down view, the scribed lines 105 may be straight lines extending along the edges of the carrier 50. Portions of the first plurality of the routing layers 64 and the second plurality of the routing layers 64, portions of the first release layer 52 and the second release layer 54, and portions of the carrier 50 may be removed together with the sealing ring 58. The removal may be done by a suitable dicing process or the like. The electrical circuit device 90 may remain embedded in the first plurality of the routing layers 64 and second plurality of the routing layers 64 after the dicing process.

FIG. 9C shows an embodiment where both sides of the carrier 50 are used for manufacturing the package substrate. The structure 107B on the bottom side of the carrier 50 is substantially identical to the structure 107A on the top side of the carrier 50 as shown in FIG. 9A, wherein like numerals refer to like features. The structures 107A and 107B on both sides of the carrier 50 may be formed by substantially identical processes, such as described with respect to FIGS. 1A through 9B. In some embodiments, the structures 107A and 107B on both sides of the carrier 50 may be formed simultaneously. In some embodiments, the structures 107A and 107B on both sides of the carrier 50 may be formed sequentially. The sealing rings 58 on both sides of the carrier 50 may be removed by a suitable dicing process along scribed lines 105.

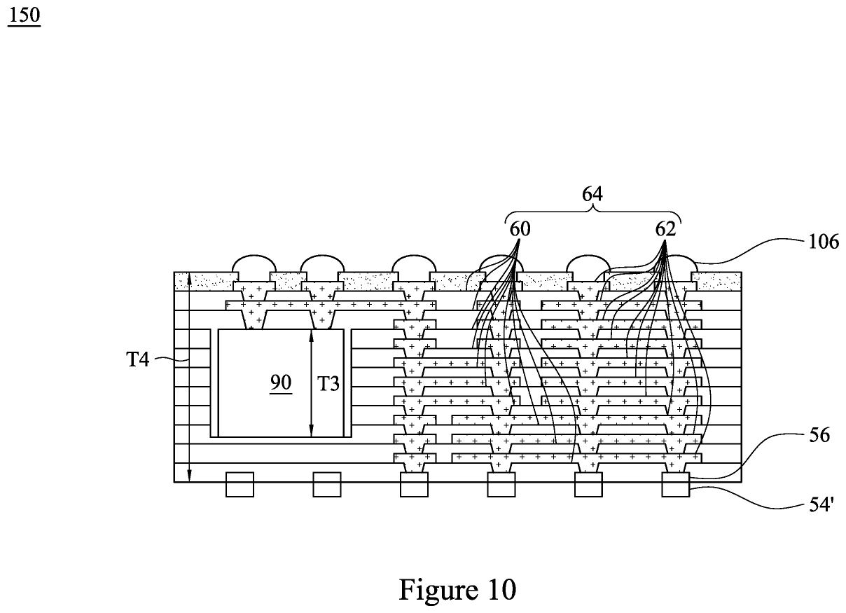

In FIG. 10, the carrier 50 (see FIG. 9A or 9B) is removed, conductive connectors 106 are formed in the openings 103 (see FIG. 9A), and conductive contacts 54′ are formed by patterning the second release layer 54 (see FIG. 9A). The carrier 50 may be removed by peeling off the carrier 50 along with the first release layer 52 after removing the sealing ring 58 (see FIG. 9A or 9B). The conductive connectors 106 may be physically and electrically connected to the conductive features 62 of the top the routing layer 64 of the second plurality of the routing layers 64. The conductive connectors 106 may be formed by initially forming a layer of conductive material in the openings 103 by methods such as evaporation, electroplating, printing, solder transfer, ball placement, or the like. Then a reflow may be performed to shape the conductive material into desired bump shapes of the conductive connectors 106. The conductive material may be a reflowable material, such as solder, copper, aluminum, gold, nickel, silver, palladium, tin, the like, or a combination thereof. Each of the conductive contacts 54′ may be physically and electrically connected to a corresponding conductive feature 56. The conductive contacts 54′ that are in contact with the dummy features of the conductive features 56 may be dummy contact pads, which may facilitate a subsequent bonding process and may be isolated from the conductive features 62 and the electrical circuit device 90. The conductive contacts 54′ may be formed by patterning the second release layer 54 using a suitable photolithography patterning process or the like. The structure shown in FIG. 10 may be referred to as a substrate structure 150. The embodiment shown in FIG. 9A may produce one substrate structure 150 (e.g., from the structure 107A), and the embodiment shown in FIG. 9C may produce two substrate structures 150 (e.g., from the structures 107A and 107B).

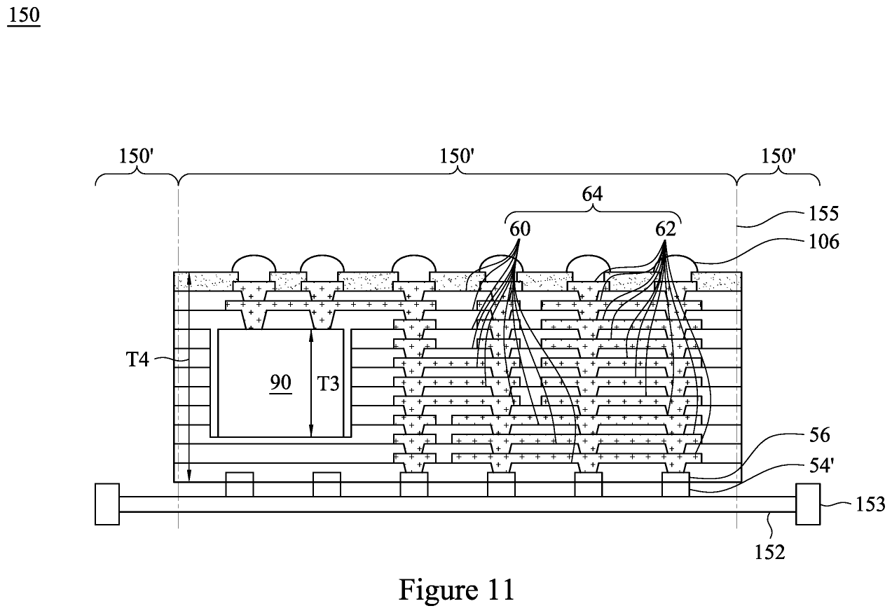

In FIG. 11, the substrate structure 150 is placed on a tape 152 supported by a frame 153, and the substrate structure 150 is singulated. The singulation process may be done along scribed lines 155 by a suitable dicing process or the like. The singulation process may produce individual package substrates 150′. As a result of the singulation process, the outer sidewalls of the routing layers 64 of each package substrate 150′ may be laterally coterminous. The electrical circuit device 90 may have a thickness T3 and the package substrate 150′ may have a thickness T4. A ratio R2 of the thickness T3 to the thickness T4 may be in a range between about 0.2 and about 0.9. Using the routing layers 64 with the woven glass fabrics 60C may allow the ratio R2 to be equal or greater than 0.2 without inducing cracks in the substrate structure 150. When the ratio R2 is greater than 0.9, the mechanical integrity of the substrate structure 150 may be negatively affected.

FIG. 11 shows the package substrate 150′ having one electrical circuit device 90 as an example. In some embodiments, the package substrate 150′ has two or more electrical circuit devices 90, and a distance between two neighboring electrical circuit devices 90 may be larger than about 400 μm to avoid interference between the two neighboring electrical circuit devices 90. FIG. 11 shows the package substrate 150′ having ten routing layers 64 as an example. In some embodiments, the package substrate 150′ has other numbers of the routing layers 64. FIG. 11 shows the first plurality of the routing layers 64 having eight routing layers 64 as an example. In some embodiments, the first plurality of the routing layers 64 has other numbers of the routing layers 64, such as a quantity larger than 50% of the total number of the routing layers 64 in the package substrate 150′. FIG. 11 shows the second plurality of the routing layers 64 having two routing layers 64 as an example. In some embodiments, the second plurality of the routing layers 64 has other numbers of the routing layers 64, such as one or more routing layers 64.

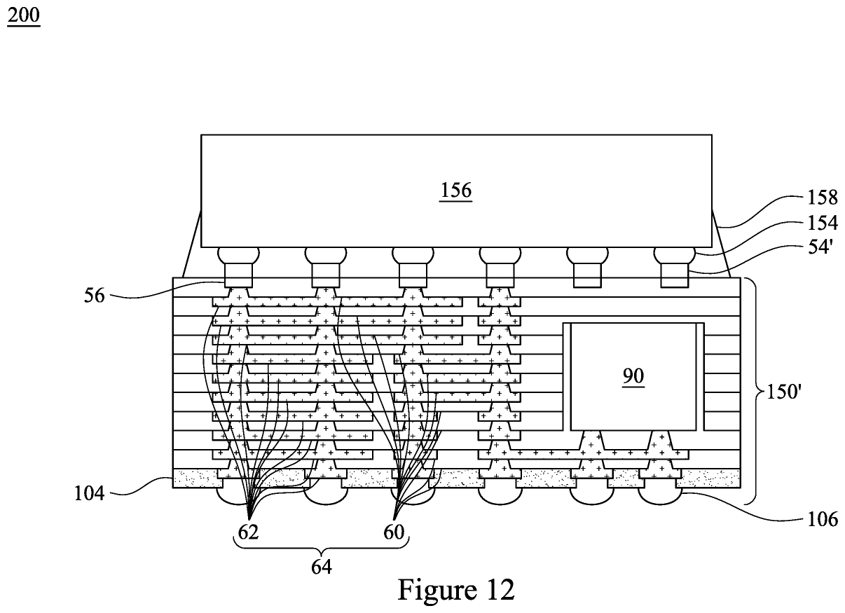

In FIG. 12, an integrated circuit package component 156 is bonded to the package substrate 150′ and an underfill 158 is formed between the integrated circuit package component 156 and the package substrate 150′. The conductive connectors 106 on the package substrate 150′ may be used to physically and electrically connect to other external devices (not shown), such as a printed circuit board or the like. The structure shown in FIG. 12 may be referred to as an integrated circuit package 200. In the embodiments where the conductive vias of the conductive features 62 have the trapezoidal shape, a smaller base of the trapezoidal shape is closer to the integrated circuit package component 156 than a wider base of the trapezoidal shape.

Embedding the electrical circuit device 90 in the package substrate 150′ may have certain benefits. When the electrical circuit device 90 is embedded in the package substrate 150′, a size of the package substrate 150′ may be reduced, which may lead to a reduced size of the integrated circuit package 200. Also, when the electrical circuit device 90 is embedded in the package substrate 150′, more conductive contacts 54′ may be disposed on the package substrate 150′ to be connected to integrated circuit package component 156, which may enhance the functionalities of the package substrate 150′ and the integrated circuit package 200. Further, when the electrical circuit device 90 is embedded in the package substrate 150′, the electrical connection pathway between the electrical circuit device 90 and the external devices connected to the conductive connectors 106 may be shortened, which may improve the electrical performance of the package substrate 150′ and the integrated circuit package 200.

The integrated circuit package component 156 may be a system-on-integrated-chip (SoIC) package, chip-on-wafer-on-substrate (CoWoS) package, InFO (integrated fan-out) package, or the like. The integrated circuit package component 156 may comprise one or more integrated circuit dies. The integrated circuit die may be a logic die (e.g., central processing unit (CPU), graphics processing unit (GPU), system-on-a-chip (SoC) die, microcontroller, etc.), a memory die (e.g., dynamic random access memory (DRAM) die, static random access memory (SRAM) die, etc.), a power management die (e.g., power management integrated circuit (PMIC) die), a radio frequency (RF) die, an interface die, a sensor die, a micro-electro-mechanical-system (MEMS) die, a signal processing die (e.g., digital signal processing (DSP) die), a front-end die (e.g., analog front-end (AFE) dies), the like, or combinations thereof. FIG. 12 shows one integrated circuit package component 156 bonded to the package substrate 150′ as an example. In some embodiments, more than one integrated circuit package component 156 is bonded to the package substrate 150′.

The integrated circuit package component 156 may be physically and electrically connected to the conductive contacts 54′ of the package substrate 150′ by conductive connectors 154. The conductive connectors 154 may be formed of same or similar materials and by same or similar methods to the conductive connectors 106. As a result, the conductive features 62 and the electrical circuit device 90 may be electrically connected to the integrated circuit package component 156. In some embodiments, some of the conductive contacts 54′ directly between the electrical circuit device 90 and the integrated circuit package component 156 are dummy contact pads, which facilitate the bonding between the integrated circuit package component 156 and the package substrate 150′ and are isolated from circuitry of the integrated circuit package 200.

The underfill 158 may be formed around the conductive connectors 154 and may encircle the integrated circuit package component 156 in the top-down view. The underfill 158 may be a continuous material extending from the integrated circuit package component 156 to the package substrate 150′. The underfill 158 may also extend on sidewalls of the integrated circuit package component 156. The underfill 158 may reduce stress and protect the joints resulting from the reflowing of the conductive connectors 154. The underfill 158 may be formed of a molding compound, epoxy, or the like. The underfill 158 may be formed by a capillary flow process after the integrated circuit package component 156 is bonded to the package substrate 150′, or may be formed by a suitable deposition process before the integrated circuit package component 156 is bonded to the package substrate 150′. The underfill 158 may be applied in liquid or semi-liquid form and then subsequently cured.

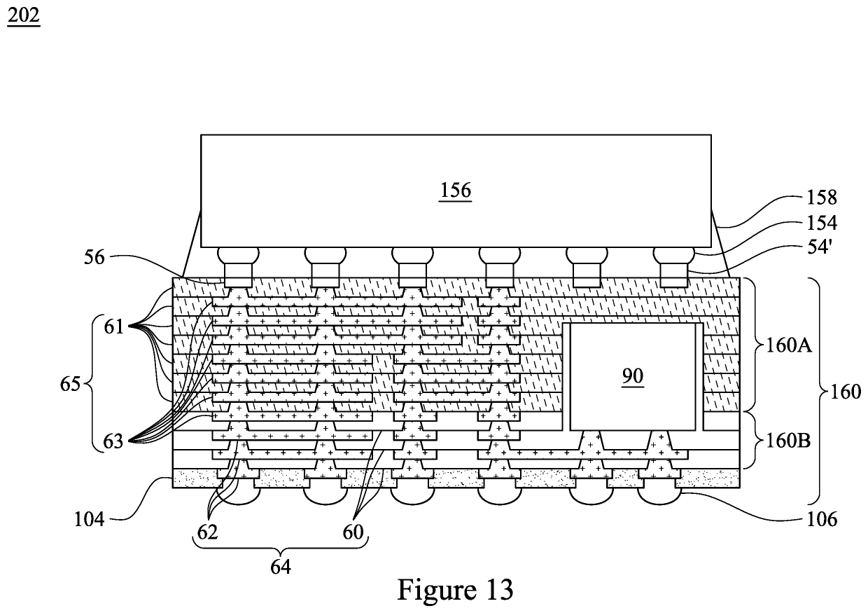

FIG. 13 shows an integrated circuit package 202, which is similar to the integrated circuit package 200 shown in FIG. 12, wherein like numerals refer to like features formed by like processes. The manufacturing processes of the integrated circuit package 202 are same or similar to the manufacturing processes of the integrated circuit package 200 described with respect to FIGS. 1A through 12. The integrated circuit package 202 comprises a package substrate 160, which is similar to the package substrate 150′ of the integrated circuit package 200. The package substrate 160 comprises two types of routing layers, which are the routing layers 64 described with respect to FIG. 4 and routing layers 65. Each of the routing layers 65 may comprise an insulating layer 61 and conductive features 62 on and through the insulating layer 61. The conductive features 63 may be same or similar to the conductive features 62 of the routing layers 64. The insulating layer 61 may comprise a polymer base and fillers embedded in the polymer base, which may be same or similar to the polymer base 60A and the fillers 60B of the insulating layer 60, respectively. The insulating layer 61 may be free of a woven glass fabric. In some embodiments, the insulating layer 61 may be an Ajinomoto build-up film (ABF). The insulating layer 61 may have a lower degree of hardness than the insulating layer 60, and the insulating layer 60 may be referred to as a hard insulating layer while the insulating layer 61 may be referred to as a soft insulating layer. The insulating layer 61 may be easier to pattern than the insulating layer 60, while the insulating layer 60 may have a lower risk of cracking during the patterning process than the insulating layer 61.

In the embodiments illustrated in integrated circuit package 202, the package substrate 160 comprises a region 160A and a region 160B. The region 160A may be in contact with the underfill 158 and disposed between the integrated circuit package component 156 and the region 160B. Each routing layer in the region 160A may be a routing layer 65 and each routing layer in the region 160B may be a routing layer 64. As a result, the region 160B may comprise consecutive routing layers 64 including the insulating layers 60 (e.g., hard insulating layers), while the region 160A may comprise consecutive routing layers 65 including the insulating layers 61 (e.g., soft insulating layers). Since the conductive connectors 106 in the protective layer 104 may be used to physically and electrically connect to other external devices (not shown), such as a printed circuit board or the like, the routing layers 64 in the region 160B may reduce the stress the other external devices may induce in package substrate 160.

About 30% or more of the routing layers in the package substrate 160 may be the routing layers 64 with the woven glass fabrics 60C and disposed in the region 160B. When less than 30% of the routing layers in the region 160B are the routing layers 64 with the woven glass fabrics 60C, cracks may occur in the package substrate 160 during the manufacturing the package substrate 160. The electrical circuit device 90 may extend through both the region 160A and the region 160B, wherein the electrical circuit device 90 may extend through one routing layer 64 in the region 160B and five routing layers 65 in the region 160A. The electrical circuit device 90 may be electrically connected to circuitry of the integrated circuit package 202 by the conductive features 62 in the routing layer 64 that is in contact with a bottom surface of the electrical circuit device 90. When the package substrate 160 is manufactured, the cavity 88 (not shown) may also may extend through one routing layer 64 in the region 160B and five routing layers 65 in the region 160A, which may be a combination the insulating layer 60 (e.g., hard insulating layer) and the insulating layers 61 (e.g., soft insulating layers) that provides improved ease of forming the cavity 88 and reduced risk of inducing cracks during the forming of the cavity 88.

The arrangement of the routing layers 64, the routing layers 65, and the electrical circuit device 90, including the numbers and locations of the routing layers 64, the routing layers 65, and the electrical circuit device 90, in the package substrate 160 shown in FIG. 13 is provided as an example. Other arrangements of the routing layers 64, the routing layers 65, and the electrical circuit device 90 are also contemplated.

Embodiments described with respect to FIGS. 1A through 12 regarding the integrated circuit package 200 may achieve certain advantages. By embedding the electrical circuit device 90 in the package substrate 150′, the sizes of the package substrate 150′ and the integrated circuit package 200 may be reduced, the functionalities of the package substrate 150′ and the integrated circuit package 200 may be enhanced, and the electrical performance of the package substrate 150′ and the integrated circuit package 200 may be improved. Further, by using the routing layers 64 with the woven glass fabrics in the package substrate 150′, the risk of inducing cracks in the package substrate 150′ during the manufacturing of the package substrate 150′ may be prevented or reduced. Therefore, the reliability of the package substrate 150′ may be also improved. Such advantages may also apply to the embodiments described with respect to FIG. 13 regarding the integrated circuit package 202.

In an embodiment, a semiconductor package includes an integrated circuit package component, wherein the integrated circuit package component includes a semiconductor die; and a package substrate physically and electrically connected to the integrated circuit package component on a first side of the package substrate, the package substrate including: a plurality of routing layers, each routing layer including: an insulating layer, the insulating layer including a polymer base; and conductive features extending through the insulating layer; and an electrical circuit device embedded in the routing layers, wherein the electrical circuit device is electrically connected to the integrated circuit package component by the conductive features of the plurality of routing layers. In an embodiment, 30% or more of the plurality of routing layers each includes a woven glass fabric embedded in the polymer base of the corresponding insulating layer. In an embodiment, the 30% or more of the plurality of routing layers with the woven glass fabrics are consecutive routing layers in on a second side of the package substrate, and wherein the second side is opposite to the first side. In an embodiment, the electrical circuit device extends through one or more routing layers with the woven glass fabrics. In an embodiment, the polymer base includes resin. In an embodiment, a first conductive via of the conductive features of the plurality of routing layers is physically and electrically connected to the electrical circuit device, and wherein the electrical circuit device is between the first conductive via and the integrated circuit package component. In an embodiment, the semiconductor package further includes an underfill extending between the integrated circuit package component and package substrate, wherein the plurality of routing layers are in contact with the underfill.

In an embodiment, a semiconductor package includes an integrated circuit package component, wherein the integrated circuit package component includes a semiconductor die; and a package substrate bonded to the integrated circuit package component on a first side of the package substrate, the package substrate including: insulating layers, wherein each of the insulating layers includes a woven glass fabric and a polymer base coated on the woven glass fabric; conductive features, wherein each of the conductive features includes a conductive line between neighboring insulating layers and a conductive via extending through the corresponding insulating layer; and an electrical circuit device, wherein a top surface of the electrical circuit device is covered by a first insulating layer of the insulating layers and a bottom surface of the electrical circuit device is in contact with a second insulating layer of the insulating layers, wherein the first insulating layer is between the electrical circuit device and the integrated circuit package component, and wherein a first conductive via of the conductive features extends through the second insulating layer to physically and electrically connect to the electrical circuit device. In an embodiment, the electrical circuit device is an integrated passive device, and wherein the electrical circuit device is electrically connected to the integrated circuit package component. In an embodiment, the semiconductor package further includes an underfill extending between the integrated circuit package component and package substrate. In an embodiment, the polymer base includes a first material and wherein the first material extends on a sidewall of the electrical circuit device. In an embodiment, each of the insulating layers further includes fillers embedded in the polymer base.

In an embodiment, a method of manufacturing a semiconductor package includes forming a package substrate, forming the package substrate including: forming a first plurality of insulating layers on a carrier, wherein each of the first plurality of insulating layers includes a woven glass fabric and a polymer base coated on the woven glass fabric; forming a first plurality of conductive features extending through the first plurality of insulating layers; forming a cavity in the first plurality of insulating layers by laser drilling; placing an electrical circuit device in the cavity; forming a second plurality of insulating layers on the electrical circuit device and the first plurality of insulating layers, wherein each of the second plurality of insulating layers includes the woven glass fabric and the polymer base coated on the woven glass fabric; forming a second plurality of conductive features extending through the second plurality of insulating layers; and removing the carrier. In an embodiment, the second plurality of conductive features are physically and electrically connected to the electrical circuit device and the first plurality of conductive features, and wherein the electrical circuit device is physically and electrically isolated from the first plurality of conductive features before forming the second plurality of conductive features. In an embodiment, forming the first plurality of conductive features includes forming a first opening in a first insulating layer of the first plurality of insulating layers by laser drilling and forming a first conductive via of the first plurality of conductive features in the first opening, wherein the first opening exposes a first conductive line of the first plurality of conductive features, and wherein the first conductive via is physically and electrically connected to the first conductive line. In an embodiment, forming the second plurality of insulating layers includes placing a first insulating layer of the second plurality of insulating layers over the electrical circuit device and melting the polymer base of the first insulating layer, and wherein a portion of the polymer base of the first insulating layer fills in a gap between the electrical circuit device and a sidewall of the cavity after melting the polymer base of the first insulating layer. In an embodiment, each of the first plurality of insulating layers further includes fillers embedded in the polymer base. In an embodiment, removing the carrier includes cutting off a seal ring on the carrier encircling the electrical circuit device in a top-down view. In an embodiment, the method of further includes bonding the package substrate to an integrated circuit package component, wherein the integrated circuit package component includes a semiconductor die; and forming underfill between the integrated circuit package component and package substrate, wherein the underfill is in contact with the first plurality of insulating layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package comprising:
an integrated circuit package component, wherein the integrated circuit package component comprises a semiconductor die; and
a package substrate physically and electrically connected to the integrated circuit package component on a first side of the package substrate, the package substrate comprising:
a plurality of routing layers, each routing layer comprising:
an insulating layer, the insulating layer comprising a polymer base; and
conductive features extending through the insulating layer; and
an electrical circuit device embedded in the routing layers, wherein the electrical circuit device is electrically connected to the integrated circuit package component by the conductive features of the plurality of routing layers.

2. The semiconductor package of claim 1, wherein 30% or more of the plurality of routing layers each comprises a woven glass fabric embedded in the polymer base of the corresponding insulating layer.

3. The semiconductor package of claim 2, wherein the 30% or more of the plurality of routing layers with the woven glass fabrics are consecutive routing layers in on a second side of the package substrate, and wherein the second side is opposite to the first side.

4. The semiconductor package of claim 2, wherein the electrical circuit device extends through one or more routing layers with the woven glass fabrics.

5. The semiconductor package of claim 1, wherein the polymer base comprises resin.

6. The semiconductor package of claim 1, wherein a first conductive via of the conductive features of the plurality of routing layers is physically and electrically connected to the electrical circuit device, and wherein the electrical circuit device is between the first conductive via and the integrated circuit package component.

7. The semiconductor package of claim 1, further comprising an underfill extending between the integrated circuit package component and package substrate, wherein the plurality of routing layers are in contact with the underfill.

8. A semiconductor package comprising:
an integrated circuit package component, wherein the integrated circuit package component comprises a semiconductor die; and
a package substrate bonded to the integrated circuit package component on a first side of the package substrate, the package substrate comprising:
insulating layers, wherein each of the insulating layers comprises a woven glass fabric and a polymer base coated on the woven glass fabric;
conductive features, wherein each of the conductive features comprises a conductive line between neighboring insulating layers and a conductive via extending through the corresponding insulating layer; and
an electrical circuit device, wherein a top surface of the electrical circuit device is covered by a first insulating layer of the insulating layers and a bottom surface of the electrical circuit device is in contact with a second insulating layer of the insulating layers, wherein the first insulating layer is between the electrical circuit device and the integrated circuit package component, and wherein a first conductive via of the conductive features extends through the second insulating layer to physically and electrically connect to the electrical circuit device.

9. The semiconductor package of claim 8, wherein the electrical circuit device is an integrated passive device, and wherein the electrical circuit device is electrically connected to the integrated circuit package component.

10. The semiconductor package of claim 8, further comprising an underfill extending between the integrated circuit package component and package substrate.

11. The semiconductor package of claim 8, wherein the polymer base comprises a first material and wherein the first material extends on a sidewall of the electrical circuit device.

12. The semiconductor package of claim 8, wherein each of the insulating layers further comprises fillers embedded in the polymer base.

13. The semiconductor package of claim 8, further comprising:
a solder resist layer on a second side of the package substrate, wherein the second side is opposite to the first side; and
external connectors extending through the solder resist layer, wherein the external connectors are physically and electrically connected the conductive features.

14. A method of manufacturing a semiconductor package, the method comprising:
forming a package substrate, forming the package substrate comprising:
forming a first plurality of insulating layers on a carrier, wherein each of the first plurality of insulating layers comprises a woven glass fabric and a polymer base coated on the woven glass fabric;
forming a first plurality of conductive features extending through the first plurality of insulating layers;
forming a cavity in the first plurality of insulating layers by laser drilling;
placing an electrical circuit device in the cavity;
forming a second plurality of insulating layers on the electrical circuit device and the first plurality of insulating layers, wherein each of the second plurality of insulating layers comprises the woven glass fabric and the polymer base coated on the woven glass fabric;
forming a second plurality of conductive features extending through the second plurality of insulating layers; and
removing the carrier.

15. The method of claim 14, wherein the second plurality of conductive features are physically and electrically connected to the electrical circuit device and the first plurality of conductive features, and wherein the electrical circuit device is physically and electrically isolated from the first plurality of conductive features before forming the second plurality of conductive features.

16. The method of claim 14, wherein forming the first plurality of conductive features comprises forming a first opening in a first insulating layer of the first plurality of insulating layers by laser drilling and forming a first conductive via of the first plurality of conductive features in the first opening, wherein the first opening exposes a first conductive line of the first plurality of conductive features, and wherein the first conductive via is physically and electrically connected to the first conductive line.

17. The method of claim 14, wherein forming the second plurality of insulating layers comprises placing a first insulating layer of the second plurality of insulating layers over the electrical circuit device and melting the polymer base of the first insulating layer, and wherein a portion of the polymer base of the first insulating layer fills in a gap between the electrical circuit device and a sidewall of the cavity after melting the polymer base of the first insulating layer.

18. The method of claim 14, wherein each of the first plurality of insulating layers further comprises fillers embedded in the polymer base.

19. The method of claim 14, wherein removing the carrier comprises cutting off a seal ring on the carrier encircling the electrical circuit device in a top-down view.

20. The method of claim 14, further comprising:
bonding the package substrate to an integrated circuit package component, wherein the integrated circuit package component comprises a semiconductor die; and
forming underfill between the integrated circuit package component and package substrate, wherein the underfill is in contact with the first plurality of insulating layers.
